(19) United States
(12) Patent Application Publication
(10) Pub. No.: US 2017/0040151 A1
(43) Pub. Date: Feb. 9, 2017

(54) GENERATOR OF TRANSIENT, HEAVY ELECTRONS AND APPLICATION TO TRANSMUTING RADIOACTIVE FISSION PRODUCTS

(71) Applicant: Tionesta Applied Research Corporation, Sequim, WA (US)

(72) Inventors: Anthony Zuppero, San Diego, CA (US); William David Jansen, San Diego, CA (US); Craig V. Bishop, Grafton, OH (US); Thomas J. Dolan, Ionia, IA (US); Paul Crone, Sequim, WA (US); William J. Saas, Westlake, OH (US)

(73) Assignee: Tionesta Applied Research Corporation, Sequim, WA (US)

(21) Appl. No.: 15/286,354

(22) Filed: Oct. 5, 2016

Related U.S. Application Data
(63) Continuation-in-part of application No. 14/933,487, filed on Nov. 5, 2015.
Application No. 14/933,487 is a continuation-in-part of application No. PCT/US15/59218, filed on Nov. 5, 2015.
(60) Provisional application No. 62/237,249, filed on Oct. 5, 2015.
(60) Provisional application No. 62/237,235, filed on Oct. 5, 2015.
(60) Provisional application No. 62/075,587, filed on Nov. 5, 2014.
(60) Provisional application No. 62/237,235, filed on Oct. 5, 2015.
(60) Provisional application No. 62/075,587, filed on Nov. 5, 2014.
(60) Provisional application No. 62/237,235, filed on Oct. 5, 2015.

(51) Int. Cl. H01J 37/34

(52) U.S. Cl. CPC H01J 37/3476; H01J 37/3464

(57) ABSTRACT

Use of adsorption, desorption, particle injection and other means to excite electrons to a region on their band structure diagram near an inflection point were the transient effective mass is elevated proportional to the inverse of curvature. These transient heavy electrons may then cause transmutations similar to transmutations catalyzed by the muons used by Alvarez at UC Berkeley during 1956 in liquid hydrogen. The heavy electrons may also control chemical reactions.

### RELATED PATENT APPLICATIONS

This patent application is a non-provisional patent application of, and claims priority to, U.S. provisional patent application No. 62/237,249, filed on Oct. 5, 2015, titled: MUON CATALYZED FUSION ATTRACTION REACTION, which has at least one inventor in common with the current patent application and the same Applicant and assignee. This patent application is also a continuation-in-part patent application of, and claims priority to, U.S. non-provisional patent application Ser. No. 14/933,487, filed on Nov. 5, 2015, titled: COMPOSITION ENABLING CONTROL OVER NEUTRALIZING RADIOACTIVITY USING MUON SURROGATE CATALYZED TRANSMUTATIONS AND QUANTUM CONFINEMENT ENERGY CONVERSION, which has at least one inventor in common with the current patent application and the same Applicant and assignee, and which claims priority from provisional patent application No. 62/237,235, filed Oct. 5, 2015, and from provisional patent application No. 62/075,587, filed Nov. 5, 2014. This patent application is also a continuation-in-part patent application of, and claims priority to, PCT patent application number PCTUS1559218, filed on Nov. 5, 2015, titled: COMPOSITION ENABLING CONTROL OVER NEUTRALIZING RADIOACTIVITY USING MUON SURROGATE CATALYZED TRANSMUTATIONS AND QUANTUM CONFINEMENT ENERGY CONVERSION, which has at least one inventor in common with the current patent application and the same Applicant and assignee, and which also claims priority from provisional patent application No. 62/237,235, filed Oct. 5, 2015, and from provisional patent application No. 62/075,587, filed Nov. 5, 2014. This patent application is also a non-provisional patent application of, and claims priority to, U.S. provisional patent application No. 62/237,235, filed on Oct. 5, 2015, which has at least one inventor in common with the current patent application and the same Applicant and assignee. The contents of all of these priority patent applications are incorporated herein by reference. If there are any conflicts or inconsistencies between this patent application and the documents that are incorporated by reference, however, this patent application governs herein.

### FIELD OF THE INVENTION

Various embodiments of this invention relate to devices and methods that produce heavy electrons. Further, particular embodiments relate to devices and methods that detect heavy electrons. Still further, certain embodiments relate to compositions of matter that include heavy electrons. Even further, Various embodiments of this invention relate to muon catalyzed fusion, chemical reaction rate control, or both.

### BACKGROUND OF THE INVENTION

Heavy electrons have many uses. In solid state and condensed matter, reactions and phenomena can depend on the effective mass of the electron. Alvarez (1957) at UC Berkeley used heavy electrons to enable transmutations. Alvarez reported observations of proton-deuteron (p-d) fusion in liquid hydrogen using a cold, heavy electron called a muon. Alvarez (1957) formed a proton-muon-deuteron (p-mu-d) tri-body. The heavy electron, a muon, attracted the p and d to itself sufficiently close to fuse. Alvarez observed that in the (p-mu-d) tri-body reaction, the muon is ejected with nearly the entire, ˜5.5 MeV binding energy.

Both Alvarez and Jackson (1957) explained how the mass of the muon took part in the reactions. No reactions between the muon and the nuclei occurred. The initial muon kinetic energy was insignificant because it was at liquid hydrogen temperature, ˜20 Kelvin. Its heavy mass was the only property of the muon that made the transmutation possible. More than hundreds of muon catalyzed fusion papers, from 1957 through the present (2016) affirm that only the muon mass was important. The transmutation was an attraction reaction of the form:

p+muon+d=3He+muon with 5.6 MeV

Because the muon appears both on the left and the right, we refer to the reaction as “catalyzed” by the muon.

In the past, producing muons has required an inefficient, high energy particle accelerator. It would be highly advantageous to avoid the need for such an accelerator. Further, with a particle accelerator, the density of muons produced in a target material is very low. Because of the low muon-to-target ratio, multi-body reactions involving two or more muons are statistically improbable. It would therefore be highly advantageous to have a high density of heavy electrons to facilitate state transitions involving multiple nuclei. Room for improvement exists over the prior art in these and other areas that may be apparent to a person of skill in the art having studied this document.

### SUMMARY OF PARTICULAR EMBODIMENTS OF THE INVENTION

This invention provides, among other things, devices, systems, and methods to make heavy electrons, which could be considered “muon-surrogate electrons” (MSE).

Various specific embodiments include, for example, certain devices to generate and detect a transient elevated density of electrons with elevated effective mass. In some such embodiments, for example, the device includes a first reaction layer placed on a first electrode and a second reaction layer placed on a second electrode. Further, in a number of embodiments, at least one of the first reaction layer or the second reaction layer includes a material that conducts electrons and readily absorbs and desorbs an injection gas. In various embodiments, the first electrode and the second electrode are electrically separate. Still further, in a number of embodiments, reactants on or in the first reaction layer, the second reaction layer, or both, are located to a depth no deeper than a characteristic mean free path of particles and excitations associated with the allowed transmutation reactions of the reactants. Even further, various embodiments include a region between the first reaction layer and the second reaction layer, and, in a number of embodiments, the region includes sputter gas and at least one of the injection gas or a substance that releases the injection gas. Further still, various embodiments include an alternating voltage having positive, negative and dead time phases. Even further still, in a number of embodiments, the alternating voltage is electrically connected to the first reaction layer and the second reaction layer, has voltage sufficient to initiate glow discharge sputtering between the first reaction layer and the second reaction layer, or both. Moreover, in various embodiments, the first reaction layer and the second reaction layer are arranged so that the material sputtered from the first reaction layer deposits on the second reaction layer during a positive phase of the alternating voltage and the material sputtered from the second reaction layer deposits on the first reaction layer during a negative phase of the alternating voltage. Furthermore, in a number of embodiments, a concentration of transmuted reactant catalyzed by heavy electrons created within the characteristic mean free path provides a measure of a density of heavy electrons created by simultaneous injection of energy, crystal momentum, and the injection gas.

In some such embodiments, when sputtering conditions are set to an onset and maintenance of sputtering, the material is sputtered from the first reaction layer to the second reaction layer and from the second reaction layer to the first reaction layer, crystallites form, the injection gas fills the crystallites, or a combination thereof. Further, in a number of embodiments, a mechanically violent bombardment, absorption, desorption and injection of the injection gas over a dimension approximately equal to a crystal unit cell and energy imparted to the crystallites simultaneously injects a broadband of crystal momentum and energy into a band structure of the crystallites, thereby energizing a useful fraction of conduction electrons to regions near at least one inflection point of a band structure diagram, and thereby creates a useful, transient density of the electrons with elevated effective mass. Further, in various embodiments, a reactant (e.g., one of the reactants) is radioactive, the dimension of crystallites dynamically formed and reformed by alternating sputtering is less than 10 times the characteristic mean free path, the characteristic mean free path of particles and excitations associated with the transmutation reactions of the reactants is nine nanometers or less, or a combination thereof. Still further, in some embodiments, a thickness of the first reaction layer is not more than 3 times the characteristic mean free path of particles and excitations associated with the transmutation reactions of the reactants, a thickness of the first reaction layer is not more than 10 times the characteristic mean free path of particles and excitations associated with the transmutation reactions of the reactants and the injection gas, or both.

In a number of embodiments, the material that conducts electrons and readily absorbs and desorbs the injection gas includes at least one of palladium, nickel, vanadium, titanium, zirconium, uranium, thorium, or tantalum, as examples. Further, in some embodiments, the injection gas includes at least one of: hydrogen isotopes, oxygen, or ions. Still further, in certain embodiments, a separation distance between the first reaction layer and the second reaction layer is no more than three times a distance across the first reaction layer. Even further, in particular embodiments, the region between the first reaction layer and the second reaction layer is exposed to a flux of photons in excess of 1 mW per square centimeter, is immersed in a magnetic field in excess of 0.5 Tesla, or both.

Other specific embodiments include, for instance, devices to generate a useful transient density of electrons with elevated effective mass. In various embodiments, for example, such a device can include a first reaction layer comprising a material that conducts electrons and readily absorbs and desorbs an injection gas, wherein the first reaction layer is placed on a first electrode, a second reaction layer that is placed on a second electrode that is electrically separate from the first electrode, and a region between the first reaction layer and the second reaction layer, the region including sputter gas and at least one of the injection gas or a substance that releases the injection gas. In a number of embodiments, an alternating voltage having positive, negative, and dead time phases is electrically connected to the first reaction layer and the second reaction layer with voltage sufficient to initiate glow discharge sputtering between the first reaction layer and the second reaction layer. Further, in various embodiments, the first reaction layer and the second reaction layer are arranged so that: the material sputtered from the first reaction layer deposits on the second reaction layer during a positive phase of the alternating voltage, the material sputtered from the second reaction layer deposits on the first reaction layer during a negative phase of the alternating voltage, or both.

Moreover, in a number of embodiments, when the sputtering conditions are set to the onset and maintenance of sputtering: the material is sputtered from the first reaction layer to the second reaction layer and from the second reaction layer to the first reaction layer, crystallites form, the injection gas fills the crystallites, or a combination thereof. Furthermore, in various embodiments, a mechanically violent bombardment, absorption, desorption and injection of the injection gas over a dimension approximately equal to a crystal unit cell, and energy imparted to the crystallites simultaneously injects a broadband of crystal momentum and energy into a band structure of the crystallites, for example, thereby energizing a useful fraction of conduction electrons to regions near at least one inflection point of a band structure diagram, and thereby creating, for instance, a useful, transient density of the electrons with elevated effective mass. Furthermore, in some embodiments, reactants are placed on or in the reaction layers and located to a depth no deeper than a characteristic mean free path of particles and excitations associated with the allowed transmutation reactions of the reactant, the concentration of reactants provides a measure of the transient density of electrons with elevated effective mass, or both.

Still other specific embodiments include highly energetic or reactive compositions of matter. Such a composition can include, for example, a crystallite whose boundaries define a region whose dimension is smaller than ten times a characteristic mean free path of particles and excitations associated with allowed muon-surrogate electron-catalyzed transmutation reactions of at least one reactant in the crystallite. Further, a number of embodiments include at least one reactant nuclide chosen from those having allowed muon-surrogate-electron-catalyzed transmutations with at least one isotope of hydrogen, at least one tracer nuclide chosen from those having allowed muon-surrogate-electron-catalyzed transmutations with at least one isotope of hydrogen, a density of at least one muon-surrogate-electrons between a hydrogen isotope and a reactant nuclide, a density of at least one muon-surrogate-electrons between a hydrogen isotope and a tracer nuclide, or a combination thereof. Still further, in various embodiments, the at least one muon-surrogate electrons migrate between isotopes of hydrogen and a tracer nuclide, the allowed tracer transmutations are catalyzed, tracer transmutation energy is released, or a combination thereof.

In a number of embodiments, the tracer is a radioactive nuclide. Further, in particular embodiments, the tracer nuclide is ¹³⁷Cesium or ⁹⁰Strontium. Still further, in some embodiments, the tracer radioactive nuclide is chosen from those that emit radiation comprising at least one of electrons and transmutation products sufficiently energetic to escape the crystallite. In addition, various other embodiments of the invention are also described herein, and other benefits of certain embodiments may be apparent to a person of skill in this area of technology.

### BRIEF DESCRIPTION OF THE DRAWINGS

The drawings provided herewith illustrate, among other things, examples of certain aspects of particular embodiments. Other embodiments may differ. Various embodiments may include aspects shown in the drawings, described in the specification (including the claims), known in the art, or a combination thereof, as examples.

FIG. 1 is a side view of a bipolar sputtering system that can produce transient, heavy electrons;

FIG. 2 is a plot that shows a segment of a band structure diagram with an inflection point where mass diverges, and shows addition of crystal momentum and energy;

FIG. 3 is a Band Structure Diagram for Pd and PdH from electronic structure calculations by Houari (2014);

FIG. 4 is a side view illustrating a reactive composition of matter; and

FIG. 5 is a plot of an expanded TOF-SIMS mass spectra of a bipolar sputtering electrode test.

### DETAILED DESCRIPTION OF EXAMPLES OF EMBODIMENTS

This patent application describes, among other things, examples of certain embodiments, and certain aspects thereof. Other embodiments may differ from the particular examples described in detail herein. Various embodiments are or concern a process of heavy electron generation, for example, that involves simultaneous injection of crystal momentum, energy, or both, for instance, to move some electrons to the desired location in the band structure diagram.

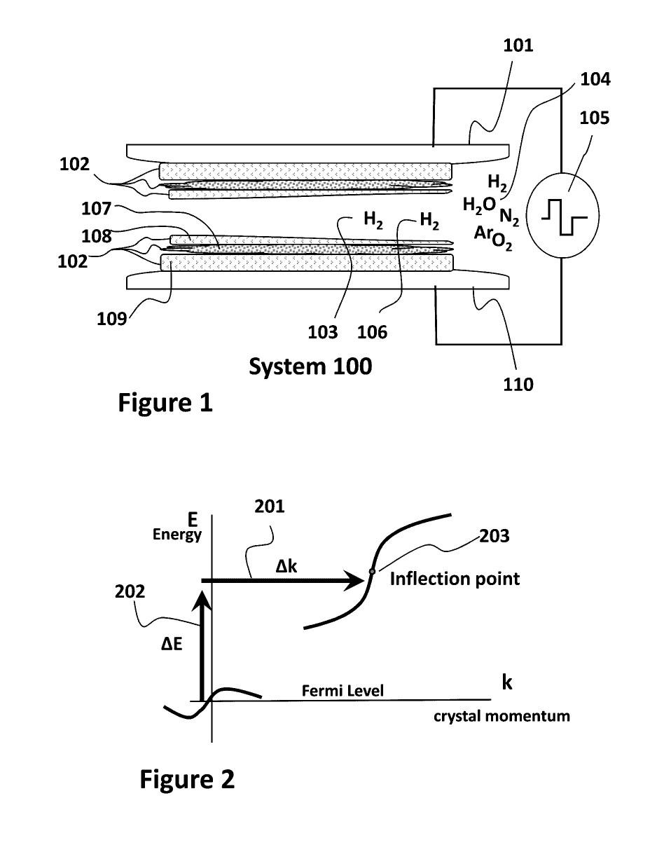

An example of a method of doing so is illustrated in FIG. 1, System 100. System 100 includes two electrically separate reaction layers 102 at least one of which comprises a material 108, 109, or both, that conducts electrons. An example of such a material is palladium. In a number of embodiments, the material readily absorbs and desorbs an injection gas 103, such as hydrogen or its isotopes. Further, various embodiments include a reactant sensor or tracer chemicals 107, such as ¹³⁷Cs, on or within a reaction depth of the reaction layer 102 surface(s) facing injection and sputter gases 103, 104, or both.

In a number of embodiments, the reaction depth is a characteristic mean free path of particles and excitations associated with the allowed transmutation reactions of any reactants found or included in the reaction layers 102. In some embodiments, for example, the reaction depth is about 10 nm. As used herein, unless stated otherwise, “about” means to within 25 percent. One embodiment uses a reaction depth of 9 nanometers, for instance. Other embodiments differ. For example, some embodiments use 3 times a mean free path.

Further, in the embodiment illustrated, reaction layer 102 is placed on a central region of electrode 101 (e.g., almost planar), for example, made of one or more materials that do not readily absorb protons or hydrogen isotopes. Still further, some embodiments arrange slightly convex electrodes with similar geometries face-to-face and with a separation that is a relatively small distance compared to the dimension across the electrode faces. As used herein, “almost planar” means planar to with ten percent of the largest overall dimension of the component (e.g., electrode). Further still, as used herein, “slightly convex” means convex with a radius of curvature that is greater than the largest overall dimension of the component (e.g., electrode). Even further, as used herein, “a relatively small distance compared to” a reference distance means that the relatively small distance is less than 25 percent of the reference distance.

Moreover, in a number of embodiments, as used herein, “Face-to-face” defines geometries where one electrode sputters material to another electrode of opposite voltage during a positive phase of an applied voltage 105, and then reverses the process during a negative phase, sputtering material back to the first electrode. In some embodiments, deposition occurs during a dead time voltage phase. In a number of embodiments, voltage 105 is applied just high enough to cause a glow discharge and initiate sputtering, for example, during positive and negative phases. Various geometries each have different advantages. For example, in particular embodiments, electrodes may consist of moving sheets like conveyor belts, for instance, with glow discharge occurring at the regions of closest approach. In some embodiments, the geometries are configured to minimize leakage of reactants from between the electrodes.

Various embodiments immerse the electrodes in a crystal momentum and reactant injection gas 103 and a sputter gas 104. Using different methods for glow discharge sputtering, one may adjust the gas pressure, composition, inter-electrode distance, voltage pulse, dead time durations, or a combination thereof, for example, such that the sputtered material deliberately forms and reforms tiny crystallites of well-mixed reaction layer material. In certain embodiments, crystallite boundaries of 3-50 nm can achieve enhanced lifetimes of the crystal momentum waves. Further, a number of embodiments limit the sputtering parameters to form crystallites with dimensions less than 10 times a characteristic mean free path, for example.

A number of embodiments deposit ions and atoms 103, 104, 106, or a combination thereof, on to the newly formed crystallites as part of the sputtering process. In various embodiments, when hydrogen is absorbed or adsorbed, it injects crystal momentum and energy, for instance, within a dimension like that of a crystal unit cell, and also imparts similar crystal momentum upon desorption. In some embodiments, in a glow discharge, accelerated hydrogen ions 103 and sputter gas 104 also impart extra kinetic energy to the crystallites simultaneously. Further, in some embodiments, reactant chemicals 106, 107, or both, may be incorporated into the reaction layer 102, for example, to be catalyzed by the heavy electrons, for instance, just as muons catalyze fusion reactions among light isotopes.

The following describes the principle of operation of various embodiments. In a number of embodiments, the effective electron mass is proportional to the inverse of the curvature of the energy versus crystal momentum locus in the band structure diagram for a solid state material:

Effective mass=²/(∂²E/∂k²)

where E is the energy, k is the crystal momentum, and is the reduced Plank constant. (C. Kittel, Introduction to Solid State Physics, Wiley, 2005, Chapter 8.) FIG. 2 shows this.

FIG. 2 explains how, in the embodiment illustrated, energizing System 100 simultaneously injects a broadband spectrum of both crystal momentum waves 201 and electron energies 202 into tiny crystallites, which are immersed in energetic injection and sputter gases 103, 104, such as hydrogen from a glow discharge. In various embodiments, the broadband nature of both energy and crystal momentum injection helps place a useful fraction of excited electrons close to any inflection point 203 of the band structure diagram in the constantly changing reaction layer and crystallites 102. Electrons close to an inflection point 203 thereby acquire a transient, elevated effective mass, in various embodiments, which may be called “muon-surrogate electrons” (MSE), which are electron quasi particles. In a number of embodiments, the result is a transient density of electrons with elevated effective mass.

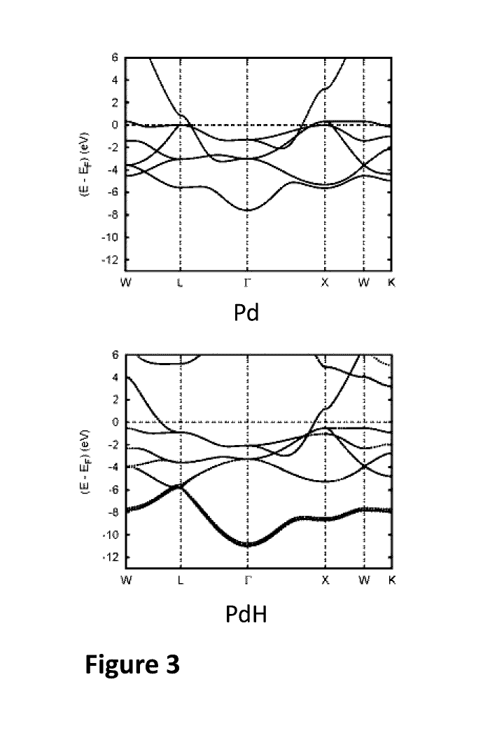

FIG. 2 shows a segment of a band structure diagram with an inflection point where mass diverges, and shows addition of crystal momentum and energy. The inflection points 203 on a band structure diagram very often involve large crystal momentum, which is associated with atom-sized distortions smaller than the crystal unit cell. Crystal momentum k scales as 1/wavelength. A large crystal momentum impulse results in wavelengths comparable to the small unit cell size. The locations of the inflection points also dynamically change with concentrations of additives, mandating a broadband injection of crystal momentum. These points can be seen in FIG. 3, where PdH exhibits an apparent inflection point near the Fermi level, and near a different location in Pd. FIG. 3 is a Band Structure Diagram for Pd and PdH from electronic structure calculations by Houari (2014).

Various embodiments use materials and injection methods that provide targeted crystal momentum and energy, for example, to place electrons deliberately close to inflection points, enhancing efficiency. Many methods and systems can achieve this. Flooding the System 100 with photons and/or hot electrons of tailored energies are examples of tailored energy injection. Phase change and material ejection and injection with tailored mass, absorption and desorption energies are examples of tailored crystal momentum injection. Energizing the optical phonon modes directly using electromagnetic radiation at terahertz frequencies provides another example. Energizing lattice motion directly by causing localized disintegration or integration of a part of a reaction region or gas provides yet another example.

In different embodiments, sputter gas 104 can be or include hydrogen, nitrogen, oxygen, argon or water (or its dissociated components), or a combination thereof, which can provide broadband energy, broadband crystal momentum during the process of forming crystallites, or both. These gasses are only examples. Other examples include Krypton and Xenon, and stable gases and materials that adsorb and desorb from crystallite surfaces, such as butane (room temperature bubbles) and methane (stable). Some embodiments include other materials that may release or provide useful gasses. Examples include single- or few-atomic layer similar materials, such as graphene.

Certain embodiments use sputtering system 100 to fill the tiny crystallites with hydrogen rapidly, thereby speeding up both absorption and ejection of hydrogen. Further, some embodiments use a sufficiently high density of sputter gas 104 so that adding one more atom to an already full crystallite causes the desorption of another atom. Still further, in various embodiments, the dimension of the reactant chemical gas 106 reservoir layer 109 is selected to be thick enough to be a reservoir of hydrogen or its isotopes. In some embodiments, for example, the reservoir layer 109 is about 40-100 nanometers thick, for instance, of palladium. Even further, some embodiments use an inter-electrode spacing, for example, ˜3 mm, electrode diameter ˜1 cm; ˜400 volt bipolar pulses about 2-3 ms at each polarity, ˜10 ms pulse period; and gas pressures ˜1.0-1.6 kPa (8-12 Torr) hydrogen.

Various embodiments include detection of the enhanced heavy electron density. Some methods to detect and measure the properties of a transient, muon-surrogate electron (MSE) use a radioisotope tracer or reactant, for example, requiring 1, 2, 3 or 4 MSE to catalyze reactions of the type

4p+4MSE+¹³⁷Cs=¹⁴¹Pr+4MSE sharing 28.6 MeV

3p+3MSE+¹³⁷Cs=¹⁴⁰Ce+3MSE sharing 23.4 MeV

2p+2MSE+¹³⁷Cs=¹³⁹La+2MSE sharing 15.3 MeV

1p+1MSE+¹³⁷Cs=¹³⁸Ba+1MSE with 9 MeV

In a number of embodiments, the rate of decrease of emitted radioactive tracer radiation or transmutation energy provides a sensor signal that can be used in a feedback loop to control System 100 operating points. In some embodiments, the tracer may be a convenient reactant whose concentration is detectable by other means. In particular embodiments, for example, a material with easily-distinguished K-alpha x-ray fluorescence may be used, for instance. One example is ¹⁸⁴W, the tungsten isotope occurring naturally with about 30% abundance. Detection can entail irradiation with an x-ray above a tungsten resonance, such as K-alpha, and detected by an x-ray detector. Another embodiment uses tracers whose transmutation products emit energies or particles sufficiently energetic to escape the crystallite.

The corresponding state transition (tri-body attraction reaction) is:

p+1MSE+¹⁸⁴W=¹⁸⁵Rh+1MSE with 5.4 MeV

p+1MSE+¹⁸⁵Rh=¹⁸⁶Os+1MSE with 6.5 MeV

2p_2MSE+¹⁸⁴W=¹⁸⁶Os+2MSE sharing 11.9 MeV.

In some embodiments, a composition of the reaction layer 102 can appear to produce trace, non-radioactive ¹⁴¹Pr from a radioactive fission product ¹³⁷CsCl taken from a commercially obtained nuclear reactor fission product mixture 107 which includes as much as about 4 times more non-radioactive ¹³³Cs and other materials. The Cs chemical compounds 107 can be buried as-received under 2-4 nm of palladium 108 on top of ˜100 nm of palladium 109 deposited on an aluminum electrode 101. The composition can include between about 400 and 600 nano Curies of ¹³⁷Cs, corresponding to about one atom tracer for every 10 to 25 atoms of a reaction layer surface atoms, or about between about 25 to 100 atoms palladium in a reaction layer 108 per radioactive atom. We hypothesize that each ¹³⁷Cs may have been surrounded by several MSE, and between 2 and 4 MSE required to affect the transmutation.

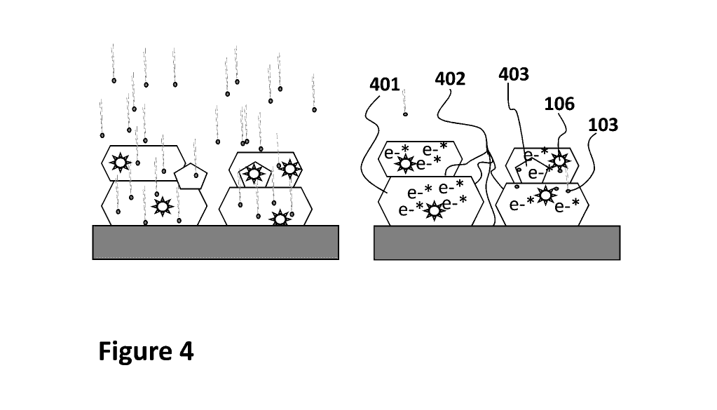

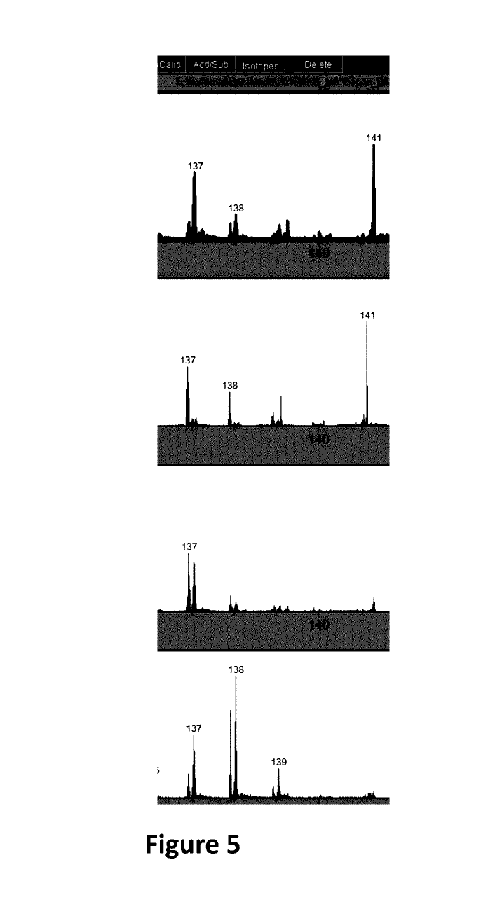

FIG. 4 describes an example of a reactive composition of matter. Certain embodiments include how to make a highly energetic or reactive composition of matter, for example, as shown in FIG. 4. The embodiment shown includes crystallite 401. Various methods can form crystallites 401 whose boundaries 402 define a region whose dimension is smaller than several times a characteristic mean free path of particles and excitations associated with allowed muon-surrogate electron-catalyzed transmutation reactions of at least one reactant in the crystallite. An example of an embodiment uses 2 to 50 nanometer crystallites, at least one reactant radioactive tracer chemical 107, a transient density of one or more heavy electrons with elevated effective mass, MSE, 403 in the vicinity of one or more tracer atoms 107 in one or more regions of the crystallite, and, in some embodiments, hydrogen and/or its isotopes as reactant chemical nuclides of injection gas 103. The reactant and tracer nuclides may be chosen, in some embodiments, from those having allowed muon-surrogate-electron-catalyzed transmutations with at least one or more isotopes of hydrogen. Various embodiments use tracer chemicals ¹³⁷Cs, ⁹⁰Sr, or other fission products exhibiting allowed transmutations.

FIG. 5 shows a highly expanded, TOF-SIMS mass spectra in a test of 4 electrodes where radioactive ¹³⁷Cs, radioactive cesium, was the tracer reactant. The spectra show both adventitious noise in the regions “to the right” of the integer mass at 137, 138, 139, 140 and 141. The noise extends slightly to the left, overlapping the masses where actual element signals should appear. One notices that the “138” signal corresponds to both the natural ¹³⁸Barium and the radioactive one. One also notices a lower intensity, anomalous 139 signal, at about 138.906, the characteristic signature of Lanthanum 139, the two-heavy electron product. With the expected even-lower reaction rate for 3 heavy electrons at the same place at the same time, one sees an even lower signal at 139.905, where ¹³⁹Cerium should reside. Spectra of un-processed electrodes do not show either Lanthanum or Cerium. Also, as expected, the relative magnitudes of the signals, near the noise limit, decrease as the number of heavy electrons needed at the same time and same place becomes larger. This suggests the heavy electron density could be interpreted to be higher for 1 electron near ¹³⁷Cs producing non-radioactive Barium, and less for 2 electrons near ¹³⁷Cs producing non-radioactive lanthanum, and, even less for 3 electrons near ¹³⁷Cs, producing cerium. If the density were closer to the limit of about 8 heavy electrons, we would see all the transmutations continue in a cascade and producing the element ¹⁴¹Nd, mass 141.907. This suggests that the isotopic abundances of the transmuted tracer give a relatively clear measure of electron density.

Using the device of System 100 and muon-surrogate-electron catalyzed transmutations, some ¹³⁷Cs appears to become non-radioactive. The non-radioactive materials would be ¹³⁸Ba, ¹³⁹La, and ¹⁴⁰Ce, and perhaps, deep in the noise, ¹⁴¹Pr. We presume the transmutation emitted between about 9 Mev (from ¹³⁸Ba), 15.3 Mev (from ¹³⁹La), 23.4 MeV from ¹⁴⁰Ce) and 28 MeV (from ¹⁴¹Pr) electron quasiparticles, and was not measured. The radioactivity decreased by about 7% with a 3.3 sigma confidence.

In a number of embodiments, the crystal momentum does not require compressive shocks, and therefore various ways can be used to cause short wavelength crystal momentum injection. In particular embodiments, for example, long wavelength crystal momentum phonons can be used. Further, in some embodiments, sufficiently intense Surface Acoustic Wave (SAW) devices may be used. Long wavelength crystal momentum folds back into the first Brillouin zone in an Umklapp process, permitting non-linear crystal momentum injection into the short wavelength region of the first Brillouin zone.

Various embodiments include ways to control chemical reactions on or in a material, for instance, by controlling effective mass. For example, a SAW generator has been used as a substrate for a 100 nm palladium catalyst. When energized to near its maximum power, catalyzed chemical oxidation reactions of alcohol, CO and other materials accelerated dramatically. Further, particular ways to inject crystal momentum and energy include protons surmounting junction barriers, such as alternate layers of palladium and nickel or oxides, and immersion in a magnetic field in excess of 0.5 Tesla. Similarly, various ways to raise electron energy can be used including irradiating with photons in excess of 1 mW/cm².

Various specific embodiments include, for example, certain devices to generate and detect a transient elevated density of electrons with elevated effective mass. System 100 shown in FIG. 1 is an example. In the embodiment illustrated, system 100 includes first reaction layer 102 placed on first electrode 101 and second reaction layer 107, 108 placed on second electrode 110. Further, in a number of embodiments, at least one of the first reaction layer (e.g., 102) or the second reaction layer (e.g., 102 or 107, 108) includes a material that conducts electrons and readily absorbs and desorbs an injection gas (e.g., 103 shown). In some embodiments, some fraction of the injection gas (e.g., 103, for instance, hydrogen, at least one hydrogen isotope, or a combination thereof) freely flows, for example, as an atom, molecule, or ion. In some embodiments, for example, the fraction is in excess of 0.1 percent. Other embodiments may differ. In particular embodiments, for example, free flowing protons are ionized quasi particles. Further, in certain embodiments, the material is a proton plus an electron conductor. Moreover, in some embodiments, the reaction region material (e.g., of layer 102, 108, or both) is selected so that the injection gas (e.g., 103) or reactant is free flowing, for example, as a delocalized atom or ion in the material. Further still, in certain embodiments, the injection gas or hydrogen, for example, is adjacent to the reactant (e.g., ¹³⁷Cs). Various embodiments can include, for instance, free ions, raw protons moving like raw electrons in a conductor metal, free atoms, for example, free to move or diffuse in the (e.g., palladium) conductor metal, atoms or ions absorbed or adsorbed as a chemical compound in or on the conductor metal, or a combination thereof, as examples.

In various embodiments, the first electrode (e.g., 101) and the second electrode (e.g., 110) are electrically separate, for instance, as shown. Still further, in a number of embodiments, reactants (e.g., 106) on or in the first reaction layer (e.g., 102), the second reaction layer (e.g., 108), or both, are located to a depth no deeper than a characteristic mean free path of particles and excitations associated with the allowed transmutation reactions of the reactants (e.g., 106). Even further, various embodiments include a region (e.g., where injection gas 103 is shown) between the first reaction layer (e.g., 102) and the second reaction layer (e.g., 107, 108), and, in a number of embodiments, the region includes sputter gas (e.g., 104) and one or more of the injection gas (e.g., 103) or a substance that releases the injection gas (e.g., 103).

Various embodiments include an alternating voltage having positive, negative and dead time phases. In the embodiment shown in FIG. 1, for example, system 100 includes alternating voltage 105. In a number of embodiments, the alternating voltage (e.g., 105) is electrically connected to the first reaction layer (e.g., 102) and the second reaction layer (e.g., 107, 108), for instance, as shown, has voltage sufficient to initiate glow discharge sputtering between the first reaction layer (e.g., 102) and the second reaction layer (e.g., 107, 108), or both. Moreover, in various embodiments, the first reaction layer (e.g., 102) and the second reaction layer (e.g., 107, 108) are arranged so that the material sputtered from the first reaction layer deposits on the second reaction layer during a positive phase of the alternating voltage and the material sputtered from the second reaction layer deposits on the first reaction layer during a negative phase of the alternating voltage. An example is shown. Furthermore, in a number of embodiments, a concentration of transmuted reactant (106) catalyzed by heavy electrons (e.g., 403 shown in FIG. 4) created within the characteristic mean free path provides a measure of a density of heavy electrons (e.g., 403) created by simultaneous injection of energy, crystal momentum, and the injection gas (e.g., 103).

In some such embodiments, when sputtering conditions are set to an onset and maintenance of sputtering, the material is sputtered from the first reaction layer (e.g., 102) to the second reaction layer (e.g., 107, 108) and from the second reaction layer to the first reaction layer, crystallites (e.g., 401) form, the injection gas (e.g., 103) fills the crystallites (e.g., 401), or a combination thereof. Further, in a number of embodiments, a mechanically violent bombardment, absorption, desorption and injection of the injection gas (e.g., 103) over a dimension approximately equal to a crystal unit cell and energy imparted to the crystallites (e.g., 401) simultaneously injects a broadband of crystal momentum and energy into a band structure of the crystallites (e.g., 401), thereby energizing a useful fraction of conduction electrons to regions near one or more inflection points (e.g., 203 shown in FIG. 2) of a band structure diagram (e.g., FIG. 2 or FIG. 3), and thereby creates a useful, transient density of the electrons (e.g., 403) with elevated effective mass. Further, in various embodiments, a reactant (e.g., one of the reactants, for instance, 106) is radioactive, the dimension of crystallites (e.g., 401) dynamically formed and reformed by alternating sputtering is less than 10 times the characteristic mean free path, the characteristic mean free path of particles and excitations associated with the transmutation reactions of the reactants (e.g., 106) is nine nanometers or less, or a combination thereof. Still further, in some embodiments, a thickness of the first reaction layer (e.g., 102) is not more than 3 times the characteristic mean free path of particles and excitations associated with the transmutation reactions of the reactants, a thickness of the first reaction layer is not more than 10 times the characteristic mean free path of particles and excitations associated with the transmutation reactions of the reactants (e.g., 106) and the injection gas (e.g., 103), or both.

In a number of embodiments, the material (e.g., of layer 102, 108, or both) that conducts electrons and readily absorbs and desorbs the injection gas (e.g., 103) includes at least one of palladium, nickel, vanadium, titanium, zirconium, uranium, thorium, or tantalum, as examples. Further, in some embodiments, the injection gas (e.g., 103) includes at least one of: hydrogen isotopes, oxygen, or ions. Still further, in certain embodiments, a separation distance between the first reaction layer (e.g., 102) and the second reaction layer (e.g., 107, 108) is no more than three times a distance across the first reaction layer. Even further, in particular embodiments, the region (e.g., where injection gas 103 is shown) between the first reaction layer (e.g., 102) and the second reaction layer (e.g., 108) is exposed to a flux of photons in excess of 1 mW per square centimeter, is immersed in a magnetic field in excess of 0.5 Tesla, or both, as examples.

Other embodiments include, for instance, devices to generate a useful transient density of electrons (e.g., 403 shown in FIG. 4) with elevated effective mass. System 100 shown in FIG. 1 is an example. In various embodiments, for example, such a device can include a first reaction layer (e.g., 102) comprising a material that conducts electrons and readily absorbs and desorbs an injection gas (e.g., 103). In a number of embodiments, the first reaction layer (e.g., 102) is placed on a first electrode (e.g., 101), a second reaction layer (e.g., 107, 108) is placed on a second electrode (e.g., 110) that is electrically separate from the first electrode, and a region (e.g., where injection gas 103 is shown) is located between the first reaction layer (e.g., 102) and the second reaction layer (e.g., 107, 108), the region including sputter gas (e.g., 104) and at least one of the injection gas (e.g., 103) or a substance that releases the injection gas. In a number of embodiments, an alternating voltage (e.g., 105) having positive, negative, and dead time phases is electrically connected to the first reaction layer (e.g., 102) and the second reaction layer (e.g., 108), for instance, with voltage sufficient to initiate glow discharge sputtering between the first reaction layer (e.g., 102) and the second reaction layer (e.g., 107, 108). Further, in various embodiments, the first reaction layer (e.g., 102) and the second reaction layer (e.g., 107, 108) are arranged (e.g., as shown) so that: the material sputtered from the first reaction layer deposits on the second reaction layer during a positive phase of the alternating voltage, the material sputtered from the second reaction layer deposits on the first reaction layer during a negative phase of the alternating voltage, or both (e.g., as shown).

Moreover, in a number of embodiments, when the sputtering conditions are set to the onset and maintenance of sputtering: the material (e.g., of layer 102, 108, or both) is sputtered from the first reaction layer to the second reaction layer, from the second reaction layer to the first reaction layer, or both. Further, in a number of such embodiments, crystallites (e.g., 401) form, the injection gas (e.g., 103) fills the crystallites (e.g., 401), or a combination thereof. Furthermore, in various embodiments, a mechanically violent bombardment, absorption, desorption and injection of the injection gas (e.g., 103) over a dimension approximately equal to a crystal unit cell, and energy imparted to the crystallites (e.g., 401) simultaneously injects a broadband of crystal momentum and energy into a band structure of the crystallites (e.g., 401), for example, thereby energizing a useful fraction of conduction electrons to regions near one or more inflection points (e.g., 203) of a band structure diagram (e.g., FIG. 2 or FIG. 3), and thereby creating, for instance, a useful, transient density of the electrons (e.g., 403) with elevated effective mass. Furthermore, in some embodiments, reactants (e.g., 106) are placed on or in the reaction layers (e.g., 102 and 107, 108) and located to a depth no deeper than a characteristic mean free path of particles and excitations associated with the allowed transmutation reactions of the reactant (e.g., 106), the concentration of reactants (e.g., 106) provides a measure of the transient density of electrons (e.g., 403) with elevated effective mass, or both.

Still other embodiments include highly energetic or reactive compositions of matter. Such a composition can include, for example, a crystallite (e.g., 401) whose boundaries (e.g., 402) define a region whose dimension is smaller than ten times a characteristic mean free path of particles and excitations associated with allowed muon-surrogate electron-catalyzed transmutation reactions of at least one reactant (e.g., 106) in the crystallite (e.g., 401). Further, a number of embodiments include one or more reactant nuclides chosen from those having allowed muon-surrogate-electron-catalyzed transmutations with at least one isotope of hydrogen, one or more tracer nuclides chosen from those having allowed muon-surrogate-electron-catalyzed transmutations with at least one isotope of hydrogen, a density of at least one muon-surrogate-electrons between a hydrogen isotope and a reactant nuclide, a density of at least one muon-surrogate-electrons between a hydrogen isotope and a tracer nuclide, or a combination thereof. Still further, in various embodiments, the at least one muon-surrogate electrons migrate between isotopes of hydrogen and a tracer nuclide, the allowed tracer transmutations are catalyzed, tracer transmutation energy is released, or a combination thereof. In a number of embodiments, the tracer is a radioactive nuclide. Further, in particular embodiments, the tracer nuclide is ¹³⁷Cesium or ⁹⁰Strontium. Still further, in some embodiments, the tracer radioactive nuclide is chosen from those that emit radiation comprising one or more of muon-surrogate electrons and transmutation products sufficiently energetic to escape the crystallite (e.g., 401).

All novel combinations are potential embodiments. Some embodiments may include a subset of elements described herein and various embodiments include additional elements as well. Further, various embodiments of the subject matter described herein include various combinations of the acts, structure, components, and features described herein, shown in the drawings, described in any documents that are incorporated by reference herein, or that are known in the art. Moreover, certain procedures can include acts such as manufacturing, obtaining, or providing components that perform functions described herein or in the documents that are incorporated by reference. The subject matter described herein also includes various means for accomplishing the various functions or acts described herein, in the documents that are incorporated by reference, or that are apparent from the structure and acts described. Each function described herein is also contemplated as a means for accomplishing that function, or where appropriate, as a step for accomplishing that function. Further, as used herein, the word “or”, except where indicated otherwise, does not imply that the alternatives listed are mutually exclusive. Even further, where alternatives are listed herein, it should be understood that in some embodiments, fewer alternatives may be available, or in particular embodiments, just one alternative may be available, as examples.

What is claimed is:

1. A device to generate and detect a transient, elevated density of electrons with elevated effective mass, the device comprising:
a first reaction layer placed on a first electrode and a second reaction layer placed on a second electrode wherein:
at least one of the first reaction layer or the second reaction layer comprises a material that conducts electrons and readily absorbs and desorbs an injection gas;
the first electrode and the second electrode are electrically separate;
reactants on or in the first reaction layer or the second reaction layer are located to a depth no deeper than a characteristic mean free path of particles and excitations associated with the allowed transmutation reactions of the reactants;
a region between the first reaction layer and the second reaction layer, the region comprising sputter gas and at least one of the injection gas or a substance that releases the injection gas;
an alternating voltage having positive, negative and dead time phases, wherein the alternating voltage is electrically connected to the first reaction layer and the second reaction layer with voltage sufficient to initiate glow discharge sputtering between the first reaction layer and the second reaction layer;
wherein:
the first reaction layer and the second reaction layer are arranged so that the material sputtered from the first reaction layer deposits on the second reaction layer during a positive phase of the alternating voltage and the material sputtered from the second reaction layer deposits on the first reaction layer during a negative phase of the alternating voltage;
a concentration of transmuted reactant catalyzed by heavy electrons created within the characteristic mean free path provides a measure of a density of heavy electrons created by simultaneous injection of energy, crystal momentum, and the injection gas.

2. The device of claim 1 wherein when sputtering conditions are set to an onset and maintenance of sputtering:
the material is sputtered from the first reaction layer to the second reaction layer and from the second reaction layer to the first reaction layer;
crystallites form;
the injection gas fills the crystallites; and
a mechanically violent bombardment, absorption, desorption and injection of the injection gas over a dimension approximately equal to a crystal unit cell and energy imparted to the crystallites simultaneously injects a broadband of crystal momentum and energy into a band structure of the crystallites, thereby energizing a useful fraction of conduction electrons to regions near at least one inflection point of a band structure diagram, and thereby creates a useful, transient density of the electrons with elevated effective mass.

3. The device of claim 1 wherein a reactant is radioactive and the reactant is one of the reactants.

4. The device of claim 1 wherein the dimension of crystallites dynamically formed and reformed by alternating sputtering is less than 10 times the characteristic mean free path.

5. The device of claim 1 wherein the characteristic mean free path of particles and excitations associated with the transmutation reactions of the reactants is nine nanometers or less.

6. The device of claim 5 wherein a thickness of the first reaction layer is not more than 3 times the characteristic mean free path of particles and excitations associated with the transmutation reactions of the reactants.

7. The device of claim 5 wherein a thickness of the first reaction layer is not more than 10 times the characteristic mean free path of particles and excitations associated with the transmutation reactions of the reactants and the injection gas.

8. The device of claim 1 wherein the material that conducts electrons and readily absorbs and desorbs the injection gas includes at least one of palladium, nickel, vanadium, titanium, zirconium, uranium, thorium, or tantalum.

9. The device of claim 1 wherein the injection gas comprises at least one of: hydrogen isotopes, oxygen, or ions.

10. The device of claim 1 wherein a separation distance between the first reaction layer and the second reaction layer is no more than three times a distance across the first reaction layer.

11. The device of claim 1 wherein the region between the first reaction layer and the second reaction layer is exposed to a flux of photons in excess of 1 mW per square centimeter.

12. The device of claim 1 wherein the region between the first reaction layer and the second reaction layer is immersed in a magnetic field in excess of 0.5 Tesla.

13. A device to generate a useful transient density of electrons with elevated effective mass, the device comprising:
a first reaction layer comprising a material that conducts electrons and readily absorbs and desorbs an injection gas, wherein the first reaction layer is placed on a first electrode;
a second reaction layer that is placed on a second electrode that is electrically separate from the first electrode;
a region between the first reaction layer and the second reaction layer, the region comprising sputter gas and at least one of the injection gas or a substance that releases the injection gas;
an alternating voltage having positive, negative, and dead time phases, wherein the alternating voltage is electrically connected to the first reaction layer and the second reaction layer with voltage sufficient to initiate glow discharge sputtering between the first reaction layer and the second reaction layer;
wherein the first reaction layer and the second reaction layer are arranged so that:
the material sputtered from the first reaction layer deposits on the second reaction layer during a positive phase of the alternating voltage; and
the material sputtered from the second reaction layer deposits on the first reaction layer during a negative phase of the alternating voltage.

14. The device of claim 13 wherein, when the sputtering conditions are set to the onset and maintenance of sputtering:
the material is sputtered from the first reaction layer to the second reaction layer and from the second reaction layer to the first reaction layer;
crystallites form;
the injection gas fills the crystallites; and
a mechanically violent bombardment, absorption, desorption and injection of the injection gas over a dimension approximately equal to a crystal unit cell, and energy imparted to the crystallites simultaneously injects a broadband of crystal momentum and energy into a band structure of the crystallites, thereby energizing a useful fraction of conduction electrons to regions near at least one inflection point of a band structure diagram, and thereby creates a useful, transient density of the electrons with elevated effective mass.

15. The device of claim 13 wherein:
reactants are placed on or in the reaction layers and located to a depth no deeper than a characteristic mean free path of particles and excitations associated with the allowed transmutation reactions of the reactant; and
the concentration of reactants provides a measure of the transient density of electrons with elevated effective mass.

16. A highly energetic or reactive composition of matter comprising:
a crystallite whose boundaries define a region whose dimension is smaller than ten times a characteristic mean free path of particles and excitations associated with allowed muon-surrogate electron-catalyzed transmutation reactions of at least one reactant in the crystallite;
at least one reactant nuclide chosen from those having allowed muon-surrogate-electron-catalyzed transmutations with at least one isotope of hydrogen;
at least one tracer nuclide chosen from those having allowed muon-surrogate-electron-catalyzed transmutations with at least one isotope of hydrogen;
a density of at least one muon-surrogate-electrons between a hydrogen isotope and a reactant nuclide;
a density of at least one muon-surrogate-electrons between a hydrogen isotope and a tracer nuclide;
wherein the at least one muon-surrogate electrons migrate between isotopes of hydrogen and a tracer nuclide, the allowed tracer transmutations are catalyzed, and tracer transmutation energy is released.

17. The composition of claim 16 where the tracer is a radioactive nuclide.

18. The composition of claim 16 where the tracer nuclide is ¹³⁷Cesium or ⁹⁰Strontium.

19. The composition of claim 16 where the tracer radioactive nuclide is chosen from those that emit radiation comprising at least one of electrons or transmutation products sufficiently energetic to escape the crystallite.
